(19) United States
(12) Patent Application Publication
(10) Pub. No.: US 2026/0130013 A1
(43) Pub. Date: May 7, 2026

(54) LIGHT-EMITTING DIODE

(71) Applicant: Xiamen San'an Optoelectronics Co., Ltd., Fujian (CN)

(72) Inventors: Xiushan ZHU, Fujian (CN); Yan LI, Fujian (CN); Zhihao BAO, Fujian (CN); Qi JING, Fujian (CN); Chun-Hsien Lee, Fujian (CN); Juchin TU, Fujian (CN); Chungying CHANG, Fujian (CN)

(73) Assignee: Xiamen San'an Optoelectronics Co., Ltd., Fujian (CN)

(21) Appl. No.: 19/378,350

(22) Filed: Nov. 4, 2025

(30) Foreign Application Priority Data
Nov. 4, 2024 (CN) 202411558179.2

(51) Int. Cl. H10H 20/831; H10H 20/814; H10H 20/832; H10H 29/49

(52) U.S. Cl. CPC H10H 20/831; H10H 20/814; H10H 20/835; H10H 29/49

(57) ABSTRACT

Disclosed is a light-emitting diode including an epitaxial stack, an insulation layer and a connection electrode. The epitaxial stack includes a first semiconductor layer, an active layer and a second semiconductor layer stacked in sequence. A trench is provided in the epitaxial stack. The connection electrode includes a first electrode electrically connected to the first semiconductor layer and a second electrode electrically connected to the second semiconductor layer. The first electrode includes a first electrode layer and a second electrode layer formed on the first electrode layer and a surface of the first semiconductor layer exposed by the trench. The first electrode layer includes a first contact layer contacting the insulation layer. The second electrode layer includes a second contact layer contacting the second semiconductor layer. A thickness of the second contact layer is less than a thickness of the first contact layer.

### CROSS-REFERENCE TO RELATED APPLICATION

The present disclosure claims the priority benefit of China application serial no. 202411558179.2, filed on Nov. 4, 2024. The entirety of the above-mentioned patent application is hereby incorporated by reference herein and made a part of this specification.

### BACKGROUND

### Technical Field

The present disclosure relates to the field of semiconductor manufacturing technology, and particularly relates to a light-emitting diode.

### Description of Related Art

Light-emitting diode (LED) is a semiconductor solid-state light-emitting device. With the continuous development of semiconductor technology, the luminous efficiency of light-emitting diodes continues to improve, making light-emitting diodes one of the most valued light sources in recent years. Commercial light-emitting diode packaging initially adopted a forward structure where gold wires connect the chip PN junction to the positive and negative electrodes of the lead frame. However, light-emitting diodes with the forward structure have problems such as large light decay, light quenching, and heat dissipation, which restrict the development of light-emitting diodes with the forward structure. To solve the problem, researchers have successively developed light-emitting diodes with a vertical structure and light-emitting diodes with a flip-chip structure.

The flip-chip light-emitting diode may be integrated and produced in bulk, featuring a simple manufacturing process and excellent performance. In flip-chip light-emitting diodes, the PN junction is bonded to the positive and negative electrodes on the substrate through eutectic bonding without the use of gold wire, thus addressing the issue of light quenching. The heat generated by the light emission may be directly conducted to the heat sink without passing through the substrate, thereby enhancing heat dissipation. Furthermore, the interconnection between the chip and the substrate shortens the electrical path, accelerates the signal transmission speed, reduces the response delay, and improves the overall performance.

However, in flip-chip light-emitting diodes, to achieve connection between the metal electrode and the light-emitting structure, through holes exposing the bottom N-type semiconductor layer are formed in the light-emitting structure, and the metal electrode is electrically connected to the N-type semiconductor layer via the through holes. Since the metal layer and reflective layer of the light-emitting diode cannot cover the through holes, this inevitably leads to reduced light extraction efficiency of the light-emitting diode during use, thereby affecting the luminous effect of the light-emitting diode.

### SUMMARY

Given the problems in the related art described above, the purpose of the present disclosure is to provide a light-emitting diode and a light-emitting device for improving the light extraction efficiency of the light-emitting diode and enhancing the luminous effect.

To achieve the above purpose and other related purposes, an aspect of the present disclosure provides a light-emitting diode, including:

An epitaxial stack, including a first semiconductor layer, an active layer and a second semiconductor layer stacked in sequence, wherein the epitaxial stack has a trench, the trench penetrates the second semiconductor layer, the active layer and a portion of the first semiconductor layer to expose a partial surface of the first semiconductor layer;

An insulation layer, formed on the epitaxial stack, wherein the insulation layer is provided with a first through hole and a second through hole;

A connection electrode, formed on the insulation layer, and including a first electrode and a second electrode, wherein the first electrode is electrically connected to the first semiconductor layer through the second through hole, the second electrode is electrically connected to the second semiconductor layer through the first through hole, the first electrode includes a first electrode layer formed on the insulation layer and a second electrode layer partially formed on the first electrode layer, the second electrode layer also includes a portion contacting the surface of the first semiconductor layer exposed by the trench through the second through hole, the first electrode layer includes a first contact layer contacting the insulation layer, the second electrode layer includes a second contact layer contacting the surface of the first semiconductor layer; wherein a thickness of the second contact layer is less than a thickness of the first contact layer.

Another aspect of the present disclosure also provides a light-emitting diode, including:

An epitaxial stack, including a first semiconductor layer, an active layer and a second semiconductor layer stacked in sequence, wherein the epitaxial stack has a trench, the trench penetrates the second semiconductor layer, the active layer and a portion of the first semiconductor layer to expose a partial surface of the first semiconductor layer;

An insulation layer, formed on the epitaxial stack, wherein the insulation layer is provided with a first through hole and a second through hole;

A connection electrode, formed on the insulation layer, including a first electrode and a second electrode, wherein the first electrode is electrically connected to the first semiconductor layer through the second through hole, the second electrode is electrically connected to the second semiconductor layer through the first through hole, the first electrode includes a contact layer, the contact layer includes a first contact portion formed on the insulation layer and a second contact portion formed on the surface of the first semiconductor layer exposed by the trench, wherein a thickness of the second contact portion is less than a thickness of the first contact portion.

Another aspect of the present disclosure also provides a light-emitting device, including a circuit substrate and a plurality of light-emitting elements connected to the circuit substrate, wherein the light-emitting elements include the light-emitting diode of the present disclosure.

As described above, the light-emitting diode and the light-emitting device provided by the present disclosure have at least the following advantageous effects:

In a first aspect, the light-emitting diode of the present disclosure includes an epitaxial stack, an insulation layer and a connection electrode. The connection electrode includes a first electrode and a second electrode. The first electrode is electrically connected to a first semiconductor layer. The first electrode includes a contact layer. The contact layer includes a first contact portion and a second contact portion. The first contact portion is formed on the insulation layer. The second contact portion is formed on a surface of the first semiconductor layer exposed by a trench. A thickness of the first contact portion is greater than a thickness of the second contact portion. The relatively thin first contact portion effectively improves a reflectivity of the first electrode. The relatively thick second contact portion may ensure good adhesion between the first electrode and the insulation layer, thereby ensuring that the light-emitting diode has a good structural stability and a good operation reliability.

In a second aspect, in the light-emitting diode of the present disclosure, the first electrode includes a first electrode layer and a second electrode layer. The first electrode layer is formed on the insulation layer. The second electrode layer is formed on the first electrode layer and on the surface of the first semiconductor layer exposed by the trench. The first electrode layer includes a first contact layer in contact with the insulation layer. The second electrode layer includes a second contact layer in contact with the surface of the first semiconductor layer. By making a thickness of the second contact layer less than a thickness of the first contact layer, the reflectivity of the first electrode is further improved, enabling the light-emitting diode to have an improved light extraction efficiency. Meanwhile, the relatively thick second contact layer may ensure a good adhesion effect between the first electrode and the insulation layer, thereby ensuring the structural stability and the operation reliability of the light-emitting diode.

### BRIEF DESCRIPTION OF THE DRAWINGS

In order to more clearly illustrate the technical solutions of the embodiments of the present disclosure, the following will briefly introduce the drawings required for use in the embodiments. It should be understood that the following drawings only show certain embodiments of the present disclosure, and therefore should not be regarded as limiting the scope. For those of ordinary skill in the art, other related drawings may also be obtained based on these drawings without creative effort.

FIG. 1 shows a structural diagram of a light-emitting diode provided by Embodiment One of the present disclosure.

FIG. 1A to FIG. 1D respectively show partial enlarged views of regions M1 to M4 in the light-emitting diode shown in FIG. 1.

FIG. 2 shows a structural diagram of an epitaxial stack in the light-emitting diode shown in FIG. 1.

FIG. 3 shows a structural diagram of a first insulation layer in the light-emitting diode shown in FIG. 1.

FIG. 4 shows a top view of a structure of a connection electrode in the light-emitting diode shown in FIG. 1.

FIG. 5 shows a top view of a structure of the epitaxial stack shown in FIG. 2.

FIG. 6 shows a schematic diagram of a variation curve of a reflectivity versus a wavelength of the connection electrode provided by Embodiment One of the present disclosure.

FIG. 7 shows a top view of a structure of the light-emitting diode shown in FIG. 1.

FIG. 8 shows an enlarged structural view of a region M5 in the light-emitting diode shown in FIG. 7.

FIG. 9 shows a structural diagram of a transparent conductive layer in the light-emitting diode provided by Embodiment One of the present disclosure.

FIG. 10 shows a top view of a structure of the transparent conductive layer shown in FIG. 9.

FIG. 11 shows a structural diagram of a second insulation layer in the light-emitting diode provided by Embodiment One of the present disclosure.

FIG. 12 shows a top view of a structure of the second insulation layer shown in FIG. 11.

FIG. 13 shows a structural diagram of a metal layer in the light-emitting diode provided by Embodiment One of the present disclosure.

FIG. 14 shows a structural diagram of the light-emitting diode provided by Embodiment Two of the present disclosure.

FIG. 14A and FIG. 14B respectively show partial enlarged views of regions M6 and M7 in the light-emitting diode shown in FIG. 14.

FIG. 15 shows a top view of a structure of the transparent conductive layer in the light-emitting diode provided by Embodiment Three of the present disclosure.

FIG. 16 shows a structural diagram of the light-emitting diode having a metal barrier layer provided by Embodiment Four of the present disclosure.

FIG. 17 shows a structural diagram of the first insulation layer having an insulation barrier layer provided by Embodiment Five of the present disclosure.

FIG. 18 shows a structural diagram of the light-emitting device provided by Embodiment Six of the present disclosure.

### DESCRIPTION OF THE EMBODIMENTS

The following describes the implementation modes of the present disclosure through specific embodiments. Those skilled in the art may easily understand other advantages and effects of the present disclosure from the content disclosed in the specification of the present disclosure. The present disclosure may also be implemented or applied through other different specific embodiments, and various details in the present disclosure may also be modified, changed or combined in various ways based on different viewpoints and applications without departing from the spirit of the present disclosure.

In the description of the present disclosure, it should be noted that the terms “first” and “second” are used for descriptive purposes only and cannot be understood as indicating or implying relative importance; the terms “center”, “longitudinal”, “lateral”, “upper”, “lower”, “front”, “rear”, “left”, “right”, “vertical”, “horizontal”, “top”, “bottom”, “inner”, “outer” and other indicated orientations or positional relationships are based on the orientations or positional relationships shown in the drawings, and are only for the convenience of describing and simplifying the description of the present disclosure, and cannot be understood as limitations on the present disclosure. The terms “install”, “connect”, “connection” should be understood in a broad sense, for example, it may be a fixed connection or a detachable connection. When a layer is referred to as being “between” two layers, it may be the only layer between the two layers, or there may be one or more intervening layers. For those skilled in the art, the specific meanings of the above terms in the present disclosure may be understood according to specific circumstances.

For the problem of low light extraction efficiency of light-emitting diodes in the related art, to improve the luminous effect of light-emitting diodes, the present embodiment provides a light-emitting diode, including:

An epitaxial stack, including a first semiconductor layer, an active layer and a second semiconductor layer stacked in sequence, wherein the epitaxial stack has a trench, the trench penetrates the second semiconductor layer, the active layer and a portion of the first semiconductor layer to expose a partial surface of the first semiconductor layer;

An insulation layer, formed on the epitaxial stack, wherein the insulation layer is provided with a first through hole and a second through hole;

A connection electrode, formed on the insulation layer, and including a first electrode and a second electrode, wherein the first electrode is electrically connected to the first semiconductor layer through the second through hole, the second electrode is electrically connected to the second semiconductor layer through the first through hole, the first electrode includes a first electrode layer formed on the insulation layer and a second electrode layer partially formed on the first electrode layer, the second electrode layer also includes a portion that contacts the surface of the first semiconductor layer exposed by the trench through the second through hole, the first electrode layer includes a first contact layer in contact with the insulation layer, the second electrode layer includes a second contact layer in contact with the surface of the first semiconductor layer; wherein a thickness of the second contact layer is less than a thickness of the first contact layer. The second contact layer has a relatively small thickness, effectively improving a reflectivity of the first electrode with respect to light, so that the light-emitting diode has an improved light extraction efficiency. The first contact layer has a relatively large thickness, and therefore has a better adhesion property, thereby improving the adhesion effect of the first electrode and ensuring that the light-emitting diode has a good structural stability and a good operation reliability.

Optionally, the first contact layer is a metal chromium layer, a metal nickel layer or a metal titanium layer, and the thickness of the first contact layer is 10 Å˜100 Å;

The second contact layer is a metal chromium layer, a metal nickel layer or a metal titanium layer, and the thickness of the second contact layer is 3 Å˜25 Å.

Optionally, the first electrode layer further includes a first metal reflective layer formed on the first contact layer. The second electrode layer further includes a second metal reflective layer formed on the second contact layer. A thickness of the first metal reflective layer is equal to a thickness of the second metal reflective layer. The first contact layer and the second contact layer respectively form reflective structures with the first metal reflective layer and the second metal reflective layer, thereby improving the reflective effect of the first electrode. By controlling the thickness of the first contact layer and the second contact layer, light absorption may be reduced and the light extraction effect of the light-emitting diode may be enhanced.

Optionally, a reflectivity of the first electrode layer is less than a reflectivity of the second electrode layer. The first electrode layer may be designed to have a relatively small reflectivity to ensure that the first electrode may have a relatively thick first contact layer, thereby ensuring that the first electrode and the insulation layer have a good adhesion effect, and simultaneously have a specific reflective effect with respect to light. The second electrode layer has a relatively large reflectivity and may further reflect light passing through the first electrode layer, so that while the first electrode has good adhesion properties, it is ensured that the first electrode has an excellent reflective effect with respect to light, thereby improving the light extraction efficiency of the light-emitting diode.

Optionally, the second electrode layer has a first portion in contact with the first electrode layer and a second portion in contact with the first semiconductor layer. In a top view of the light-emitting diode along a thickness direction of the epitaxial stack, an area of the first portion is larger than an area of the second portion. By making the area of the first portion larger than the area of the second portion, a larger contact area may be provided between the first electrode layer and the second electrode layer to ensure a good adhesion effect between the first electrode layer and the second electrode layer, thus improving the structural stability of the light-emitting diode.

Optionally, a plurality of recess portions are further provided at an outer periphery of the epitaxial stack. The recess portions penetrate the second semiconductor layer, the active layer and a portion of the first semiconductor layer along a thickness direction of the epitaxial stack to expose the partial surface of the first semiconductor layer, and the second electrode layer contacts the surface of the first semiconductor layer exposed by the recess portions through the second through hole. By providing the recess portions at the outer periphery of the epitaxial stack, current spreading may be enhanced and the uniformity of internal field strength may be improved.

Optionally, a substrate is further included, and the epitaxial stack is formed on the substrate;

In a top view of the light-emitting diode, a distance between the first electrode layer and an edge of the substrate is greater than a distance between the second electrode layer and the edge of the substrate. With a distance between an edge of the first electrode layer and an edge of the second electrode layer being an electrode layer edge spacing, a value of the electrode layer edge spacing in a region where the recess portions are located is greater than a value of the electrode layer edge spacing at other regions of the light-emitting diode. By designing the second electrode layer to completely cover the edge of the first electrode layer, it is ensured that light passing through the first electrode layer may be effectively reflected, improving the light extraction efficiency of the light-emitting diode. By regulating the electrode layer edge spacing, the electrical connection effect between the second electrode layer and the first semiconductor layer exposed by the recess portions may be ensured, thereby improving the performance of the light-emitting diode.

Optionally, the second electrode includes a third electrode layer and a fourth electrode layer. The third electrode layer includes a third contact layer formed on the insulation layer. The fourth electrode layer includes a fourth contact layer formed on the third electrode layer. A thickness of the third contact layer is greater than a thickness of the fourth contact layer. The thicker third contact layer may ensure the adhesion effect between the second electrode and the insulation layer, and the thinner fourth contact layer effectively improves the reflectivity of the second electrode, thereby improving the light extraction efficiency of the light-emitting diode.

Optionally, a first gap is provided between the first electrode layer and the third electrode layer. A second gap is provided between the second electrode layer and the fourth electrode layer. A width of the first gap is less than a width of the second gap. Such design may prevent contact between the first electrode and the second electrode, thereby ensuring electrical insulation between the first electrode and the second electrode.

Optionally, the third electrode layer further includes a third metal reflective layer formed on the third contact layer. The fourth electrode layer further includes a fourth metal reflective layer formed on the fourth contact layer. A thickness of the third metal reflective layer is equal to a thickness of the fourth metal reflective layer.

Optionally, the third contact layer is a metal chromium layer, a metal nickel layer or a metal titanium layer, and the thickness of the third contact layer is 10 Å˜100 Å;

The fourth contact layer is a metal chromium layer, a metal nickel layer or a metal titanium layer, and the thickness of the fourth contact layer is 3 Å˜25 Å. The third contact layer and the fourth contact layer respectively form total reflection structures with the third metal reflective layer and the fourth metal reflective layer, thus improving the reflectivity of the second electrode. By controlling the thickness of the third contact layer and the fourth contact layer, absorption of light may be reduced, thereby enhancing the light extraction effect of the light-emitting diode.

This embodiment further provides another light-emitting diode, including:

An epitaxial stack, including a first semiconductor layer, an active layer and a second semiconductor layer sequentially stacked, wherein the epitaxial stack has a trench, the trench penetrates the second semiconductor layer, the active layer and a portion of the first semiconductor layer to expose a partial surface of the first semiconductor layer;

An insulation layer, formed on the epitaxial stack, wherein the insulation layer is provided a first through hole and a second through hole;

A connection electrode, formed on the insulation layer, and including a first electrode and a second electrode, wherein the first electrode is electrically connected to the first semiconductor layer through the second through hole, the second electrode is electrically connected to the second semiconductor layer through the first through hole, the first electrode includes a contact layer, the contact layer includes a first contact portion formed on the insulation layer and a second contact portion formed on the surface of the first semiconductor layer exposed by the trench, and a thickness of the second contact portion is less than a thickness of the first contact portion. The relatively thin first contact portion effectively improves the reflectivity of the first electrode, and the relatively thick second contact portion may ensure good adhesion between the first electrode and the insulation layer, thereby ensuring that the light-emitting diode has a good structural stability and a good operation reliability.

Optionally, in a top view of the light-emitting diode, an area of the first contact portion is larger than an area of the second contact portion. By making the area of the first contact portion larger than the area of the second contact portion, the first electrode and the insulation layer may have a larger contact area to ensure the good adhesion effect between the first electrode and the insulation layer, thus improving the structural stability of the light-emitting diode.

Optionally, the light-emitting diode further includes a transparent conductive layer and a metal layer, the insulation layer includes a first insulation layer and a second insulation layer;

The transparent conductive layer is formed on the epitaxial stack, which may enhance a current spreading effect and improve the performance of the light-emitting diode;

The second insulation layer is formed on the epitaxial stack, covering the transparent conductive layer, wherein the second insulation layer has a third through hole and a fourth through hole. The third through hole exposes the transparent conductive layer, and the fourth through hole exposes the surface of the first semiconductor layer exposed by the trench;

The metal layer is formed on the second insulation layer, and in contact with the transparent conductive layer through the third through hole;

The first insulation layer is formed on the metal layer and covers the second insulation layer. The second insulation layer may enhance the uniformity of current distribution and may also serve as a reflective structure for light radiated by the epitaxial stack. The metal layer may achieve electrical connection between the second electrode and the second semiconductor layer, has a good light reflection effect, and cooperates with the second insulation layer to form a light reflection structure, thereby improving light extraction efficiency.

Optionally, the transparent conductive layer is provided with a plurality of fifth through holes spaced apart from each other. The fifth through holes expose the second semiconductor layer and are arranged in a staggered manner with the third through hole. By providing the plurality of fifth through holes, the absorption effect of the transparent conductive layer with respect to light radiated by the active layer may be reduced, thereby improving the light extraction efficiency and the luminous effect of the light-emitting diode.

Optionally, the light-emitting diode further includes a metal barrier layer, formed on the second insulation layer and covering the metal layer. The first through hole exposes the metal barrier layer. The second electrode contacts the metal barrier layer through the first through hole. The metal barrier layer may block the components of the metal layer from thermal diffusion or electromigration, and avoid the reduction of reflectivity of the metal layer caused by oxidation of the surface of the metal layer, thereby ensuring the operation reliability of the light-emitting diode.

Optionally, the second insulation layer includes an insulation barrier layer covering the metal layer. The insulation barrier layer is provided with a sixth through hole. The second electrode contacts the metal layer through the first through hole and the sixth through hole. The insulation barrier layer may block the components of the metal layer from thermal diffusion or electromigration, and avoid the reduction of reflectivity of the metal layer caused by oxidation of the surface of the metal layer, ensuring the operation reliability of the light-emitting diode.

Optionally, the light-emitting diode further includes:

A third insulation layer, located on a side of the first insulation layer away from the second insulation layer, and covering the connection electrode, the third insulation layer is provided with an opening exposing the connection electrode;

A pad electrode, located on a side of the connection electrode away from the first insulation layer, and electrically connected to the connection electrode through the opening.

The present embodiment further provides a light-emitting device, including a circuit substrate and a plurality of light-emitting elements connected to the circuit substrate. The light-emitting elements include any one of the light-emitting diodes described in the foregoing embodiments. Since the light-emitting device includes the light-emitting diode described in the present disclosure, the light-emitting device also has the above advantageous effects.

The following will provide a detailed introduction to the solution of the present disclosure in combination with specific embodiments.

### Embodiment One

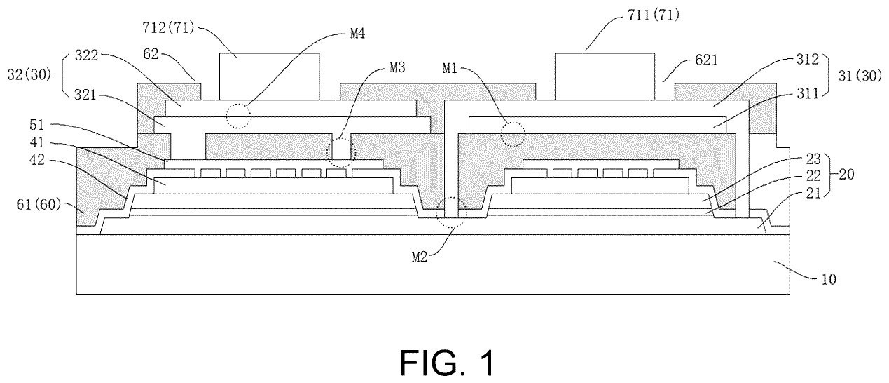

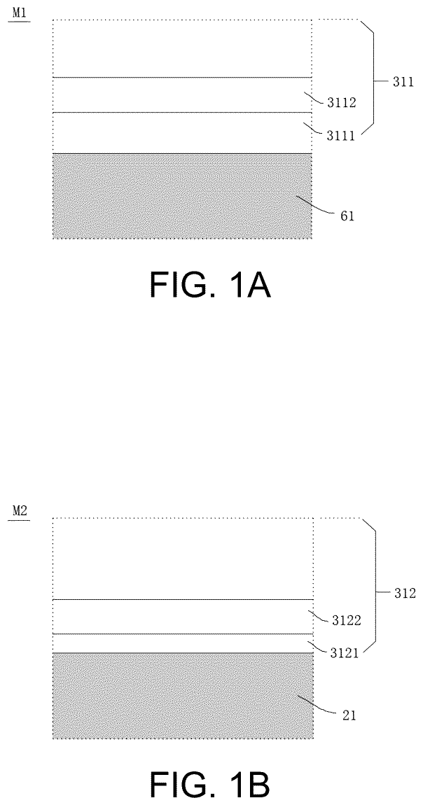

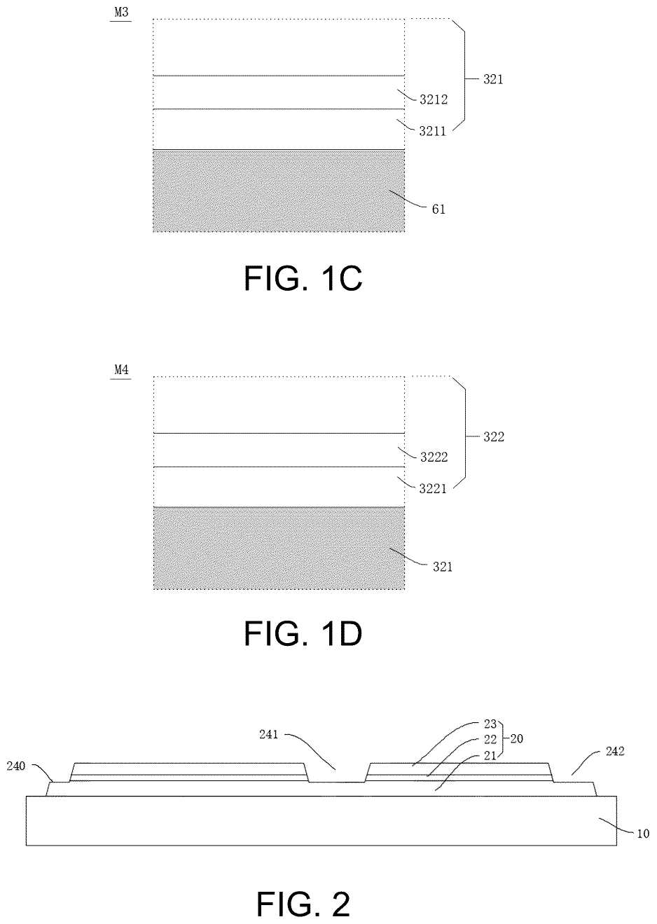

The present embodiment provides a light-emitting diode, referring to FIG. 1, including an epitaxial stack 20, an insulation layer 60 and a connection electrode 30. The epitaxial stack 20 is a light-emitting structure of the light-emitting diode, and capable of radiating light of specific wavelengths, for example, radiating a blue light with a wavelength of 450 nm, a yellow light with a wavelength of 550 nm or a red light with a wavelength of 620 nm, etc., the connection electrode 30 is electrically connected to the epitaxial stack 20.

Referring to FIG. 2, the epitaxial stack 20 includes a first semiconductor layer 21, an active layer 22 and a second semiconductor layer 23 stacked in sequence. The epitaxial stack 20 is provided with a trench 241. The trench 241 penetrates the second semiconductor layer 23, the active layer 22 and a portion of the first semiconductor layer 21 to expose a partial surface of the first semiconductor layer 21. Optionally, the first semiconductor layer 21 has a first surface and a second surface opposite to each other. The second surface is a surface of the first semiconductor layer 21 on a side close to the active layer 22 and connected to the active layer 22. The first surface is a surface of the first semiconductor layer 21 on a side away from the active layer 22. The trench 241 exposes the second surface of the first semiconductor layer 21. Further, the shape of the trench 241 may be circular, elliptical, rectangular, polygonal or other acceptable shapes.

In alternative embodiments, the first semiconductor layer 21, the active layer 22 and the second semiconductor layer 23 may be semiconductor layers made of Group III gallium nitride series-based compounds, for example, formed by GaN, AlN, InGaN, AlGaN, InAlGaN and including one or more of the above materials. The first semiconductor layer 21, the active layer 22 and the second semiconductor layer 23 may be formed by a chemical vapor deposition process, a hydride vapor phase epitaxy process, a molecular beam epitaxy process or other acceptable methods. The first semiconductor layer 21 and the second semiconductor layer 23 have different conductive types, may respectively provide electrons and holes. For example, the first semiconductor layer 21 is an N-type semiconductor layer, and the second semiconductor layer 23 is a P-type semiconductor layer, or, the first semiconductor layer 21 is a P-type semiconductor layer, and the second semiconductor layer 23 is an N-type semiconductor layer. The active layer 22 is a layer where electrons and holes are combined to output light of specific wavelengths. The active layer 22 may be formed by a multilayer semiconductor thin film with a single-layered or multi-layered quantum well structure having potential well layers and barrier layers alternately stacked. The active layer 22 adjusts the wavelength of output light by controlling a material ratio or a constitution of ingredients.

Further, the first semiconductor layer 21 is an N-type semiconductor layer, and capable of providing electrons. The first semiconductor layer 21 may be formed by injecting N-type dopants such as Si, Ge, Se, Te, C and other materials. The second semiconductor layer 23 is a P-type semiconductor layer, and capable of providing holes. The second semiconductor layer 23 may be formed by injecting P-type dopants such as Mg, Zn, Be, Ca, Sr, Ba and other materials.

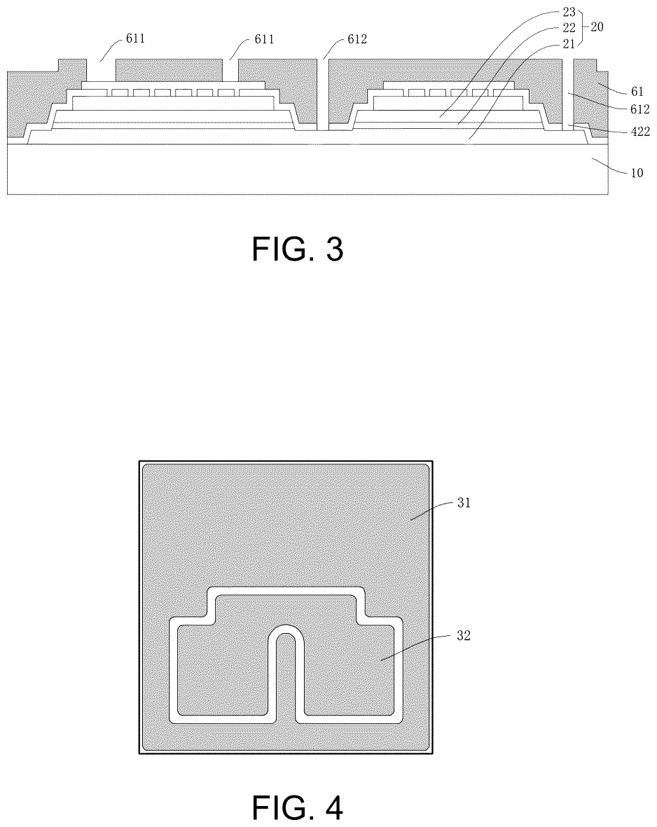

In this embodiment, referring to FIG. 1 and FIG. 3, the insulation layer 60 is formed on the epitaxial stack 20, and located between the connection electrode 30 and the epitaxial stack 20. The insulation layer 60 is provided with a through hole 611 and a through hole 612, with a thickness direction of the epitaxial stack 20 as a vertical direction. Optionally, in a top view of the light-emitting diode along the vertical direction, contour structures of the through hole 611 and the through hole 612 may be circular, elliptical, polygonal or other suitable structures.

In alternative embodiments, the insulation layer 60 includes a first insulation layer 61. The first insulation layer 61 is located between the connection electrode 30 and the epitaxial stack 20. A material of the first insulation layer 61 includes a material that is transparent with respect to light radiated by the active layer 22. Optionally, the material of the first insulation layer 61 includes one or more of SiO₂, SiN, SiOₓN_{y}, TiO₂, Si₃N₄, Al₂O₃, TiN, AlN and other transparent inorganic insulation materials, for example, the first insulation layer 61 is a SiO₂ layer. Further, the first insulation layer 61 may be formed by a physical vapor deposition process or a chemical vapor deposition process and other methods, then the first insulation layer 61 is patterned by photolithography and etching methods to form the through hole 611 and the through hole 612.

Referring to FIG. 1 and FIG. 4, the connection electrode 30 is formed on the insulation layer 60, and located at a side of the second semiconductor layer 23 away from the active layer 22. The connection electrode 30 includes a first electrode 31 and a second electrode 32. The second electrode 32 is electrically connected to the second semiconductor layer 23. The first electrode 31 is electrically connected to the first semiconductor layer 21. Optionally, the first semiconductor layer 21 is an N-type semiconductor layer, and the first electrode 31 may transport electrons to the first semiconductor layer 21. The second semiconductor layer 23 is a P-type semiconductor layer, and the second electrode 32 may transport holes to the second semiconductor layer 23. The first electrode 31 includes a first electrode layer 311 and a second electrode layer 312. The first electrode layer 311 is formed on the first insulation layer 61, and the second electrode layer 312 is formed on the first electrode layer 311 and on the first semiconductor layer 21 exposed by the trench 241. Optionally, in a top view of the light-emitting diode, the second electrode layer 312 completely covers the first electrode layer 311. The second electrode layer 312 contacts the surface of the first semiconductor layer 21 through the through hole 612. Referring to FIG. 1A and FIG. 1B, the first electrode layer 311 includes a first contact layer 3111 in contact with the first insulation layer 61, and the second electrode layer includes a second contact layer 3121 in contact with the surface of the first semiconductor layer 21. A thickness of the second contact layer 3121 is less than a thickness of the first contact layer 3111.

In alternative embodiments, the connection electrode 30 may be a single-layered structure or a stack structure. A material of the connection electrode 30 includes a metal material, such as titanium (Ti), tungsten (W), aluminum (Al), indium (In), tin (Sn), nickel (Ni), platinum (Pt), chromium (Cr), gold (Au), titanium tungsten (TiW) and other metals or includes one or more of the above materials. Further, the connection electrode 30 adopts a stack structure, the first contact layer 3111 and the second contact layer 3121 are respectively a first layer of a stack structure of the first electrode layer 311 and a stack structure of the second electrode layer 312, having a good adhesion effect, and configured to respectively secure positions of the first electrode layer 311 and the second electrode layer 312 in the light-emitting diode, thereby ensuring the structural stability of the light-emitting diode.

In the related art, when the connection electrode adopts a stack structure, the first layer of the stack structure normally has a large thickness, and the first layer with large thickness may reduce the reflection effect of the connection electrode, which in turn reduces the light extraction efficiency of the light-emitting diode. In this embodiment, the first electrode 31 includes the first electrode layer 311 and the second electrode layer 312. The first electrode layer 311 includes the first contact layer 3111, and the second electrode layer 312 includes the second contact layer 3121. The thickness of the first contact layer 3111 is greater than the second contact layer 3121. The relatively thin second contact layer 3121 may ensure a good ohmic contact between the first electrode 31 and the first semiconductor layer 21 while improving the reflection effect of the first electrode 31 with respect to light, thereby enhancing the light extraction efficiency of the light-emitting diode. The first contact layer 3111 has a relatively thick thickness, thereby improving the adhesion effect between the first electrode 31 and the first insulation layer 61, ensuring that the light-emitting diode has a good structural stability and a good operation reliability.

In alternative embodiments, the first contact layer 3111 is a metal chromium layer, a metal nickel layer or a metal titanium layer. The thickness of the first contact layer 3111 is 10 Å˜100 Å. Optionally, the thickness of the first contact layer 3111 may be, for example, 10 Å, 30 Å, 50 Å, 80 Å, 100 Å or other suitable values. Further, the first contact layer 3111 is a metal chromium layer. The second contact layer 3121 is a metal chromium layer, a metal nickel layer or a metal titanium layer. The thickness of the second contact layer 3121 is 3 Å˜25 Å. Optionally, the thickness of the second contact layer 3121 may be, for example 3 Å, 5 Å, 10 Å, 15 Å, 25 Å or other suitable values. Further, the second contact layer 3121 is a metal chromium layer. In practical applications, the metal chromium layer, the metal nickel layer, and the metal titanium layer have good adhesion properties, especially the metal chromium layer. By setting the first contact layer 3111 with an appropriate thickness, it is possible to ensure the adhesion effect between the first contact layer 3111 and the first insulation layer 61 while minimizing the absorption of light. The thinner second contact layer 3121 may improve the reflection effect of the first electrode 31 with respect to light, thereby improving the luminous effect, structural stability and operation reliability of the light-emitting diode.

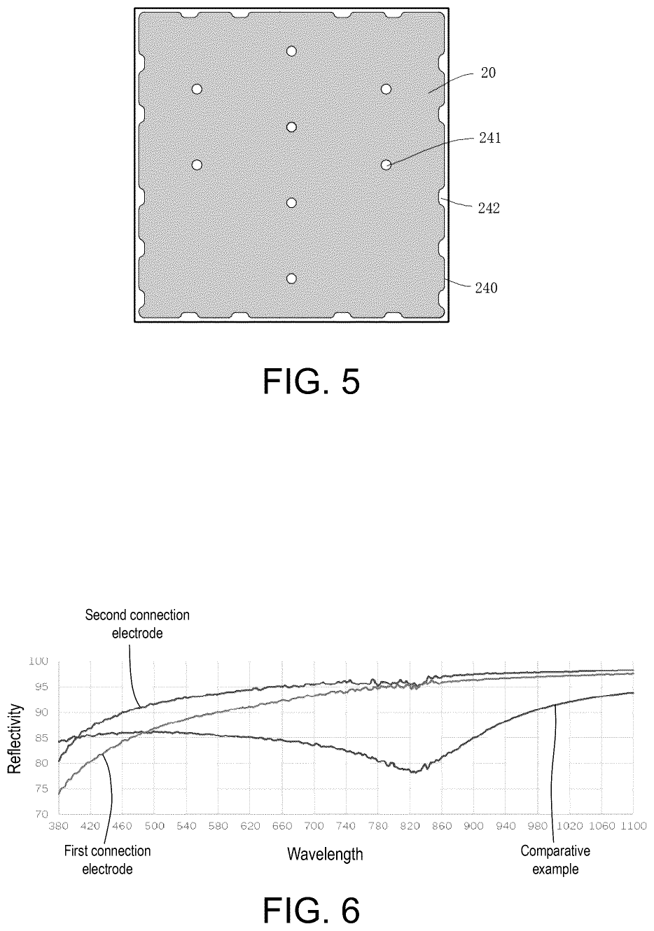

In alternative embodiments, referring to FIG. 5, an outer periphery of the epitaxial stack 20 is further provided with a plurality of recess portions 242. The recess portions 242 penetrate the second semiconductor layer 23, the active layer 22 and a portion of the first semiconductor layer 21 along the vertical direction to expose the partial surface of the first semiconductor layer 21. The second electrode layer 312 contacts the surface of the first semiconductor layer 21 exposed by the recess portions 242 through the through hole 612. Optionally, the number of trenches 241 and the number of recess portions 242 are both multiple. The plurality of trenches 241 are spaced apart in the epitaxial stack 20. The plurality of recess portions 242 are spaced apart at the outer periphery of the epitaxial stack 20. By providing the plurality of trenches 241 and the recess portions 242 spaced apart from each other, current spreading may be enhanced and the uniformity of internal field strength may be improved.

In this embodiment, referring to FIG. 1, the light-emitting diode further includes a substrate 10. The substrate 10 is located at a side of the first semiconductor layer 21 away from the active layer 22. A material of the substrate 10 may be a transparent material. Optionally, the material of the substrate 10 is sapphire, gallium nitride, silicon carbide, gallium arsenide or other suitable materials. Further, the material of the substrate 10 includes sapphire, which has good light transmittance and conductivity.

In alternative embodiments, referring to FIG. 2 and FIG. 5, an edge mesa 240 is formed at the outer periphery of the epitaxial stack 20. The edge mesa 240 exposes the second surface of the first semiconductor layer 21. The epitaxial stack 20 may be patterned by photolithography and etching to form the edge mesa 240, the trenches 241 and the recess portions 242. In a top view of the light-emitting diode, the recess portions 242 are closer to a central area of the light-emitting diode compared to the edge mesa 240 at other positions.

In alternative embodiments, as shown in FIG. 8, in a top view of the light-emitting diode, a distance between the first electrode layer 311 and an edge of the substrate 10 is greater than a distance between the second electrode layer 312 and the edge of the substrate 10. With the distance between the edge of the first electrode layer 311 and the edge of the second electrode layer 312 being an electrode layer edge spacing D1, a value of the electrode layer edge spacing D1 at a region where the recess portions 242 are located is greater than a value of the electrode layer edge spacing D1 at other regions of the light-emitting diode. By designing the second electrode layer 312 to completely cover the edge of the first electrode layer 311, effective reflection of light passing through the first electrode layer 311 may be ensured, thereby improving the light extraction efficiency of the light-emitting diode. By regulating the electrode layer edge spacing, the electrical connection effect between the second electrode layer 312 and the first semiconductor layer 21 exposed by the recess portions 242 is ensured, thus improving the performance of the light-emitting diode.

In this embodiment, both the first electrode layer 311 and the second electrode layer 312 are stack structures. The first electrode layer 311 and the second electrode layer 312 may be respectively formed by a physical vapor deposition process, a magnetron sputtering process or other suitable methods.

In alternative embodiments, referring to FIG. 1A and FIG. 1B, the first electrode layer 311 further includes a first metal reflective layer 3112 formed on the first contact layer 3111. The second electrode layer 312 further includes a second metal reflective layer 3122 formed on the second contact layer 3121. Optionally, a thickness of the first metal reflective layer 3112 is equal to or substantially equal to a thickness of the second metal reflective layer 3122. The description “substantially equal to” may be interpreted in a sense that a difference ratio between the thickness of the first metal reflective layer 3112 and the thickness of the second metal reflective layer 3122 is not greater than 10%. For example, an absolute value of a ratio of the difference between the thickness of the first metal reflective layer 3112 and the thickness of the second metal reflective layer 3122 to the thickness of the second metal reflective layer 3122 is less than 10%. Further, both the first metal reflective layer 3112 and the second metal reflective layer 3122 are metal silver layers. The first metal reflective layer 3112 and the first contact layer 3111, as well as the second metal reflective layer 3122 and the second contact layer 3121, cooperatively form reflective structures, improving the reflective effect of the first electrode 31 and enhancing the luminous effect of the light-emitting diode.

In alternative embodiments, the reflectivity of the first electrode layer 311 is less than the reflectivity of the second electrode layer 312. The first electrode layer 311 may be designed to have a relatively small reflectivity, which may ensure that the first electrode 31 has a relatively thick first contact layer 3111, thereby ensuring the good adhesion effect between the first electrode 31 and the first insulation layer 61, while simultaneously having a specific reflective effect with respect to light. The second electrode layer 312 has a relatively large reflectivity, which may further reflect light passing through the first electrode layer 311, while ensuring that the first electrode 31 has a good adhesion property, ensuring that the first electrode 31 has an improved reflective effect with respect to light, thus improving the light extraction efficiency of the light-emitting diode.

Further, the reflectivity of the first electrode layer 311 is 78%˜90%, the reflectivity of the second electrode layer 312 is 89%˜95%. Specifically, referring to FIG. 6, for example, both the first contact layer 3111 and the second contact layer 3121 are metal chromium layers. The thickness of the first contact layer 3111 is 10 Å, the thickness of the second contact layer 3121 is set to 5 Å. A comparative example made of other materials is provided, for example, Al is used as the first layer of the comparative example. By testing the first electrode layer 311, the second electrode layer 312 and the comparative example, their reflectivity with respect to different wavelengths is obtained. The reflectivity of the first electrode layer 311 with respect to blue light at a wavelength of 450 nm is 83.2%, the reflectivity with respect to red light at a wavelength of 620 nm is 91.1%, the reflectivity of the second electrode layer 312 with respect to blue light at a wavelength of 450 nm is 89.2%, and the reflectivity with respect to red light at a wavelength of 620 nm is 94.3%. It may be seen that for light at a wavelength of 450 nm and higher, the thinner second electrode layer 312 has an improved reflective effect. Therefore, by setting the thinner second contact layer 3121, the reflectivity of the connection electrode 30 is improved, thus enhancing the light extraction efficiency of the light-emitting diode.

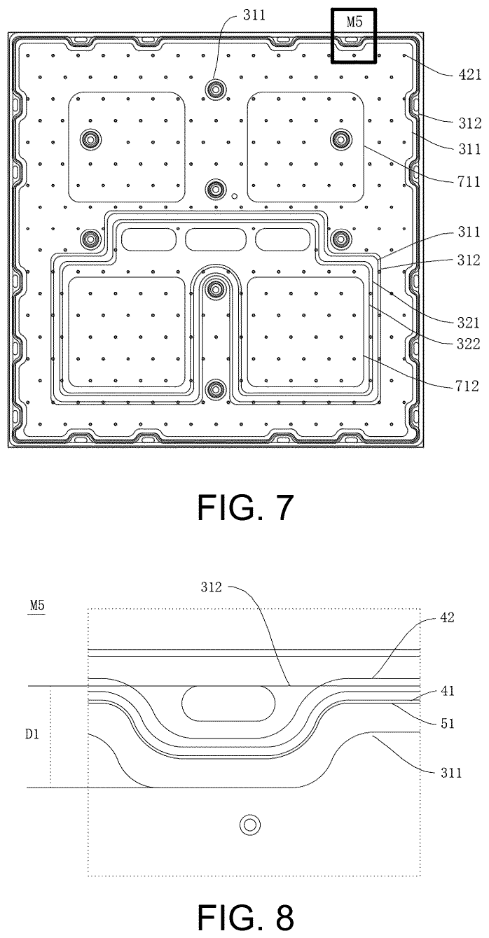

In alternative embodiments, referring to FIG. 7 and FIG. 8, the second electrode layer 312 has a first portion in contact with the first electrode layer 311, and a second portion in contact with the first semiconductor layer 21. An area of the first portion is larger than an area of the second portion. Optionally, in a top view of the light-emitting diode, a ratio between the area of the first portion and the area of the second electrode layer 312 is greater than 80%. By setting the second electrode layer 312 and the first electrode layer 311 to have a large contact area, the first electrode layer 311 and the first insulation layer 61 also have a large contact area, thus effectively ensuring that both the first electrode layer 311 and the second electrode layer 312, and both the first electrode layer 311 and the first insulation layer 61 have a good adhesion effect, thus improving the structural stability of the light-emitting diode.

In this embodiment, referring to FIG. 1C and FIG. 1D, the second electrode 32 includes a third electrode layer 321 and a fourth electrode layer 322. The second electrode 32 may be made of the same material as the first electrode 31, or may be made of different materials. The third electrode layer 321 includes a third contact layer 3211 formed on the first insulation layer 61. The fourth electrode layer 322 includes a fourth contact layer 3221 formed on the third electrode layer 321. A thickness of the third contact layer 3211 is greater than a thickness of the fourth contact layer 3221. Similar to the first electrode 31, the relatively thick third electrode layer 321 may improve the adhesion effect between the second electrode 32 and the first insulation layer 61, and the relatively thin fourth electrode layer 322 may improve the reflective effect of the second electrode 32, thus enhancing the luminous effect of the light-emitting diode.

In alternative embodiments, the third contact layer 3211 is a metal chromium layer, a metal nickel layer or a metal titanium layer. For example, the third contact layer 3211 may be designed as a metal chromium layer, the thickness of the third contact layer 3211 is 10 Å˜100 Å, optionally, the thickness of the third contact layer 3211 may be, for example, 10 Å, 30 Å, 50 Å, 70 Å, 100 Å or other suitable values. The fourth contact layer 3221 is a metal chromium layer, a metal nickel layer or a metal titanium layer, for example, the fourth contact layer 3221 may be designed as a metal chromium layer, the thickness of the fourth contact layer 3221 is 3 Å˜25 Å, optionally, the thickness of the fourth contact layer 3221 may be, for example, 3 Å, 5 Å, 10 Å, 20 Å, 25 Å or other suitable values. By controlling the thickness of the third contact layer 3211 and the thickness of the fourth contact layer 3221, the absorption of light by the second electrode may be reduced, thus enhancing the light extraction efficiency of the light-emitting diode.

In this embodiment, the structure of the second electrode 32 may be a single-layered structure or a stack structure. Optionally, both the third electrode layer 321 and the fourth electrode layer 322 are stack structures. The third electrode layer 321 further includes a third metal reflective layer 3212 formed on the third contact layer 3211. The fourth electrode layer 322 further includes a fourth metal reflective layer 3222 formed on the fourth contact layer 3221. Further, a thickness of the fourth metal reflective layer 3222 is equal to or substantially equal to a thickness of the third metal reflective layer 3212, and the third metal reflective layer 3212 and the fourth metal reflective layer 3222 may be, for example, a metal silver layer or other suitable material layers. Reflective structures are formed between the third metal reflective layer 3212 and the third contact layer 3211, and between the fourth metal reflective layer 3222 and the fourth contact layer 3221, thus ensuring that the second electrode 32 has a good reflective effect and enhancing the light extraction efficiency of the light-emitting diode.

In alternative embodiments, referring to FIG. 7, in a top view of the light-emitting diode, an area of the third electrode layer 321 is larger than an area of the fourth electrode layer 322. Optionally, a first gap is provided between the first electrode layer 311 and the third electrode layer 321, a second gap is provided between the second electrode layer 312 and the fourth electrode layer 322, and a width of the first gap is smaller than a width of the second gap. By controlling the width of the first gap and the width of the second gap, the first electrode 31 and the second electrode 32 are spaced apart from each other, thus ensuring electrical insulation between them.

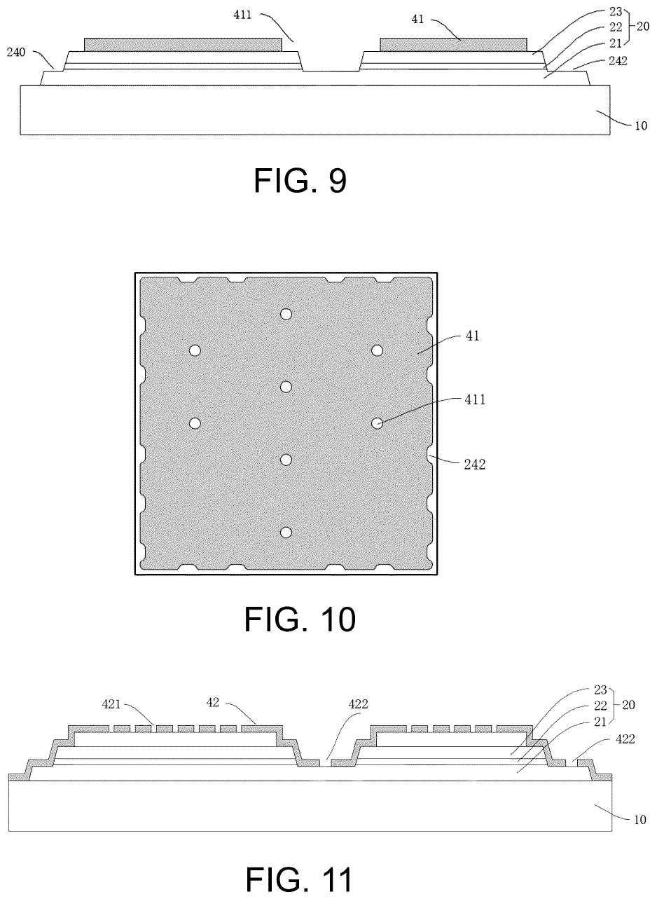

In this embodiment, referring to FIG. 9 and FIG. 10, the light-emitting diode may further include a transparent conductive layer 41. The transparent conductive layer 41 is located on a side of the second semiconductor layer 23 away from the active layer 22. The transparent conductive layer 41 is formed on the second semiconductor layer 23, and at least covers a partial surface of the second semiconductor layer 23. Optionally, the transparent conductive layer 41 may be formed on the second semiconductor layer 23 through a chemical vapor deposition process, a physical vapor deposition process or other acceptable methods, and forms an ohmic contact with the second semiconductor layer 23. The transparent conductive layer 41 may enhance a current spreading effect and improve the performance of the light-emitting diode. A material of the transparent conductive layer 41 includes materials that are transparent to light radiated by the epitaxial stack 20. Optionally, the transparent conductive layer 41 includes ITO, InO, SnO, CTO, ATO, ZnO, GaP or includes a combination of one or more of the above materials. Further, a thickness of the transparent conductive layer 41 is 5 nm to 100 nm.

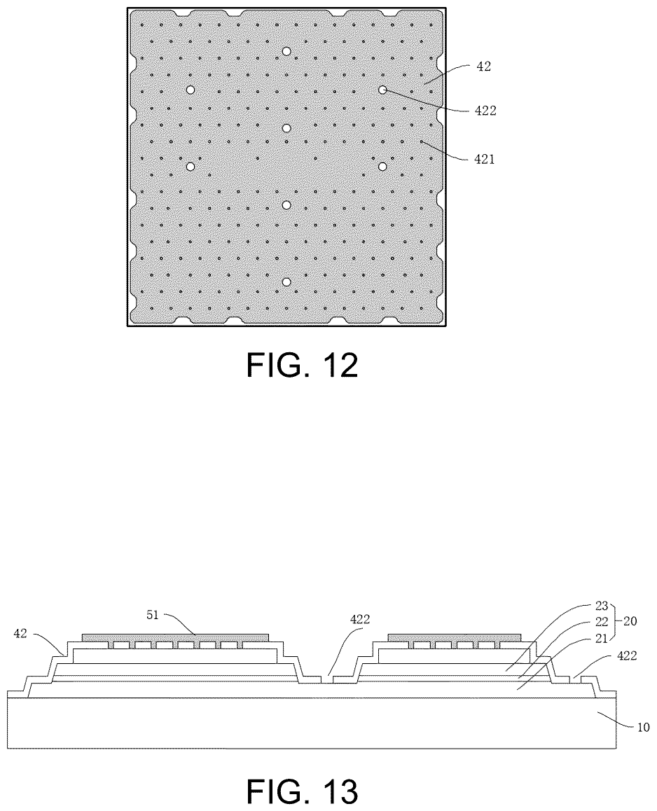

In this embodiment, referring to FIG. 11 and FIG. 12, in the light-emitting diode, the insulation layer 60 may further include a second insulation layer 42. The second insulation layer 42 is located on a side of the second semiconductor layer 23 away from the active layer 22, and at least covers a portion of the transparent conductive layer 41. Optionally, the second insulation layer 42 is formed on the epitaxial stack 20, and covers the transparent conductive layer 41 and an exposed surface of the epitaxial stack 20. The material of the second insulation layer 42 includes materials that are transparent to light radiated by the epitaxial stack 20. Optionally, a material of the second insulation layer 42 includes one or more of transparent inorganic insulation materials such as SiO₂, SiN, SiOₓN_{y}, TiO₂, Si₃N₄, Al₂O₃, TiN, AlN, for example, the second insulation layer 42 is a SiO₂ layer.

Through holes 421 and 422 are provided in the second insulation layer 42. In a top view of the light-emitting diode, the contour structures of the through holes 421 and 422 may be circular, elliptical, polygonal or other suitable structures. The through hole 421 penetrates the second insulation layer 42 along the vertical direction and exposes the second semiconductor layer 23. The through hole 422 is located directly above the trench 241 along the vertical direction to expose at least a portion of the second surface located within the trench 241. Optionally, the number of through holes 421 is multiple. In a top view of the light-emitting diode, the plurality of through holes 421 are distributed in an array with intervals in the second insulation layer 42. After forming the second insulation layer 42, the second insulation layer 42 may be patterned through photolithography and etching to form the through hole 421 to expose the second semiconductor layer 23, or further form the through hole 422 to expose the second surface. In a top view of the light-emitting diode, the through hole 612 and the through hole 422 at least partially overlap each other. Optionally, in a top view of the light-emitting diode, the through hole 612 and the through hole 422 coincide with each other. The through hole 612 and the through hole 422 may be formed through one etching process.

In an optional embodiment, the second insulation layer 42 includes a distributed Bragg reflector layer (DBR). The DBR layer is a multi-layered structure of insulation films with different refractive indices alternately stacked. Optionally, the DBR layer at least covers the transparent conductive layer 41. The multi-layered structure of the DBR layer is a structure of the first insulation film having a first refractive index and the second insulation film having a second refractive index stacked alternately. Further, the second insulation layer 42 is formed by a material having a refractive index lower than the refractive index of the second semiconductor layer 23, and serves to improve the reflection effect with respect to light, thereby improving light extraction efficiency. The second insulation layer 42 may also be a stack structure of a DBR layer and a SiO₂ layer, with the SiO₂ layer formed on the DBR layer.

In this embodiment, referring to FIG. 1 and FIG. 13, the light-emitting diode may further include a metal layer 51. The first insulation layer 61 is formed on the metal layer 51 and covers the second insulation layer 42. The metal layer 51 is formed on the second insulation layer 42 and located between the first insulation layer 61 and the second insulation layer 42. The second electrode 32 contacts the metal layer 51 through the through hole 611. The metal layer 51 is electrically connected to the transparent conductive layer 41 through the through hole 421, so that current applied to the metal layer 51 may be diffused through the transparent conductive layer 41. Light radiated by the epitaxial stack 20 partially transmits through the second insulation layer 42 to reach a surface of the metal layer 51 and is reflected by the metal layer 51. Optionally, the refractive index of the second insulation layer 42 is less than a refractive index of the epitaxial stack 20, so that part of the light radiated by the active layer 22 may be incident onto the metal layer 51 at a small angle. Light exceeding a total reflection angle is totally reflected back, and an improved reflection effect is achieved through the cooperation of the metal layer 51 and the second insulation layer 42. Optionally, the metal layer 51 is a single-layered or multi-layered structure formed by metal materials, for example, may be formed by one or more materials selected from Au, W, Pt, Ir, Ag, Al, Cu, Ni, Ti, Cr and other materials and their alloys.

In an optional embodiment, in a top view of the light-emitting diode, a distance between the metal layer 51 and the edge of the substrate 10 is greater than a distance between the transparent conductive layer 41 and the edge of the substrate 10, so that a contact area between the transparent conductive layer 41 and the second semiconductor layer 23 is greater than an area of the metal layer 51, thereby reducing voltage. Optionally, in a top view of the light-emitting diode, the through hole 421 is located within a projection range of the metal layer 51, so that the metal layer 51 may be electrically connected to the transparent conductive layer 41 through the through hole 421.

In this embodiment, referring to FIG. 1, the light-emitting diode further includes a third insulation layer 62. The third insulation layer 62 is located on a side of the first insulation layer 61 away from the second insulation layer 42 and covers the connection electrode 30. The third insulation layer 62 may be formed by a physical vapor deposition process or a chemical vapor deposition process or other suitable methods. The third insulation layer 62 may be a single-layered structure formed by a single material or a stack structure formed by stacking different materials. The third insulation layer 62 may be formed by materials substantially the same as the material of the first insulation layer 61, or may be formed by different materials. An opening 621 is provided in the third insulation layer 62, and the opening 621 exposes a surface of the connection electrode 30.

In this embodiment, the light-emitting diode further includes a pad electrode 71. The pad electrode 71 is located on a side of the connection electrode 30 away from the first insulation layer 61, and is electrically connected to the connection electrode 30 through the opening 621. The pad electrode 71 may be a single-layered structure or a multi-layered structure. A material of the pad electrode 71 includes one or more of Au, Sn, Ni, Pb, Ag, In, Cr, Ge, Si, Ti, W, Pt and other materials. Optionally, the pad electrode 71 includes a first pad layer 711 and a second pad layer 712. The first pad layer 711 is formed on the first electrode 31 and located on a side of the first electrode 31 away from the first insulation layer 61. The second pad layer 712 is formed on the second electrode 32 and located on a side of the second electrode 32 away from the first insulation layer 61.

As described above, by setting the second contact layer 3121 with a smaller thickness, the light-emitting diode of this embodiment ensures a good ohmic contact between the first electrode 31 and the first semiconductor layer 21, improves the reflectivity of the first electrode 31, and thereby enhancing the luminous effect of the light-emitting diode. By utilizing the first contact layer 3111 with a larger thickness, a good adhesion between the first electrode 31 and the first insulation layer 61 is ensured, thus improving the structural stability and the operation reliability of the light-emitting diode.

### Embodiment Two

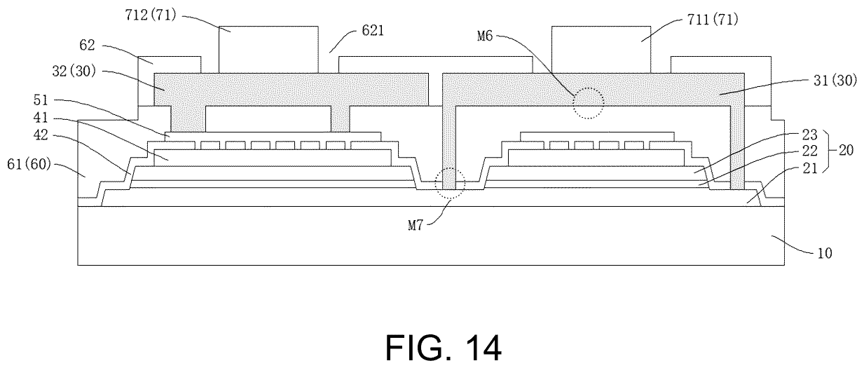

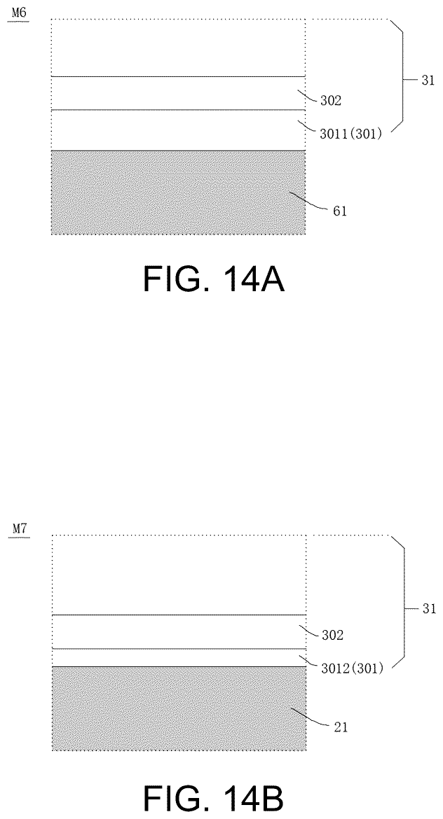

This embodiment provides another light-emitting diode, referring to FIG. 14, including an epitaxial stack 20, an insulation layer 60 and a connection electrode 30. For details of the epitaxial stack 20 and the insulation layer 60 of this embodiment, please refer to Embodiment One.

In this embodiment, referring to FIG. 14A and FIG. 14B, the connection electrode 30 is formed on the first insulation layer 61, and includes the first electrode 31 and the second electrode 32. The first electrode 31 is electrically connected to the first semiconductor layer 21 through the through hole 612, and the second electrode 32 is electrically connected to the second semiconductor layer 23 through the through hole 611. The first electrode 31 includes a contact layer 301. The contact layer 301 includes a first contact portion 3011 formed on the first insulation layer 61 and a second contact portion 3012 formed on the surface of the first semiconductor layer 21 exposed by the trench 241. Optionally, a thickness of the second contact portion 3012 is less than a thickness of the first contact portion 3011.

For parameters such as thickness and material of the first contact portion 3011, please refer to the first contact layer in Embodiment One; for parameters such as thickness and material of the second contact portion 3012, please refer to the second contact layer in Embodiment One, that is, the contact layer 301 of this embodiment corresponds to the first contact layer 3111 and second contact layer 3112 in Embodiment One. Compared to the related art, the relatively thin second contact portion 3012 may reduce absorption of light and effectively improve the reflectivity of the first electrode, thus enhancing the light extraction efficiency of the light-emitting diode. The relatively thick first contact portion 3011 may ensure a good adhesion effect between the first electrode 31 and the first insulation layer 61, thus improving the structural stability and operation reliability of the light-emitting diode.

In an optional embodiment, in a top view of the light-emitting diode, an area of the first contact portion 3011 is larger than an area of the second contact portion 3012. Optionally, in a top view of the light-emitting diode, a ratio between the area of the first contact portion 3011 and the area of the first electrode 31 is greater than 80%. The first contact portion 3011 contacts the first insulation layer 61. By designing the first contact portion 3011 to have a larger contact area, a good adhesion effect between the first electrode 31 and the first insulation layer 61 may be ensured, thus improving the structural stability of the light-emitting diode.

For parameters such as material and preparation method of the connection electrode 30, please refer to Embodiment One. Optionally, the first electrode 31 in this embodiment is a stack structure, and the contact layer 301 is the first layer of the stack structure. Further, the first electrode 31 also includes a metal reflective layer 302 formed on the contact layer 301. The metal reflective layer 302 may be, for example, a metal silver layer. The first electrode 31 may also include other material layers formed on the metal reflective layer 302. The metal reflective layer 302 cooperates with the contact layer 301 to form a reflective structure, thus effectively improving the reflectivity of the first electrode 31 and enhancing the light extraction efficiency of the light-emitting diode.

In this embodiment, the second electrode 32 may adopt the same stack structure as the first electrode 31 of this embodiment, and may also adopt the structure of the second electrode 32 described in Embodiment One, or other suitable structures. Optionally, the light-emitting diode may also include the transparent conductive layer 41, the second insulation layer 42, the metal layer 51, the pad electrode 71 and the third insulation layer 62 described in Embodiment One.

### Embodiment Three

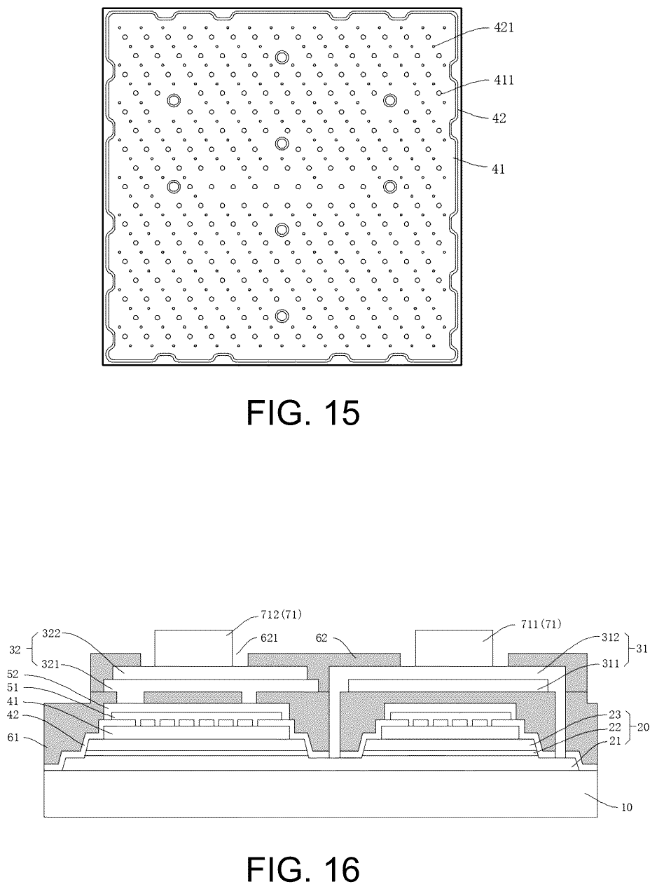

This embodiment provides another light-emitting diode, referring to FIG. 15, the same aspects as Embodiment One will not be described redundantly. The difference between this embodiment and Embodiment One is that in the light-emitting diode of this embodiment, the transparent conductive layer 41 is provided with a plurality of through holes 411. The through holes 411 penetrate the transparent conductive layer 41 along the vertical direction to expose the second semiconductor layer 23, and the through holes 411 are arranged in a staggered manner with the through holes 421. The second insulation layer 42 is filled in the through holes 411 and covers an exposed surface of the second semiconductor layer 23. By providing the through holes 411, the absorption of light by the transparent conductive layer 41 may be reduced, thus improving the light extraction efficiency of the light-emitting diode and enhancing the luminous effect of the light-emitting diode.

In an optional embodiment, the number of through holes 411 is multiple. The transparent conductive layer 41 is patterned by photolithography and etching to obtain the plurality of through holes 411 uniformly distributed in an array. In a top view of the light-emitting diode, the shape of the through holes 411 may be circular, elliptical, polygonal or other acceptable shapes. The shape of the through holes 421 may be the same as or different from the shape of the through holes 411, and the through holes 411 and the through holes 421 are arranged in a staggered manner.

### Embodiment Four

This embodiment provides another light-emitting diode, referring to FIG. 16, the same aspects as Embodiment One will not be described redundantly. The difference between this embodiment and Embodiment One is that the light-emitting diode of this embodiment further includes a metal barrier layer 52. The metal barrier layer 52 is located on a side of the second insulation layer 42 away from the transparent conductive layer 41, and covers the metal layer 51. The through hole 611 of the first insulation layer 61 exposes the metal barrier layer 52, and the second electrode 32 contacts the metal barrier layer 52 through the through hole 611.

In an optional embodiment, a material of the metal barrier layer 52 includes metal materials, such as Ti, Pt, W, In, Sn, Al, Ni, Cr, Au and other metal materials or alloy materials formed by the above metals. The metal barrier layer 52 may be a single-layered structure, or may be a stack structure formed by stacking at least two materials.

In an optional embodiment, the metal layer 51 is formed on the second insulation layer 42. The metal barrier layer 52 at least covers a partial surface of the metal layer 51. For example, the metal barrier layer 52 covers a partial surface or an entire surface of the metal layer 51 away from the second insulation layer 42, or covers a side surface of the metal layer 51 to completely wrap an exposed surface of the metal layer 51. By providing the metal barrier layer 52 to wrap the metal layer 51, the components of the metal layer 51 may be blocked from thermal diffusion or electrical diffusion, and oxidation of the surface of the metal layer 51 that causes the reflectivity of the metal layer 51 to decrease may also be avoided.

### Embodiment Five

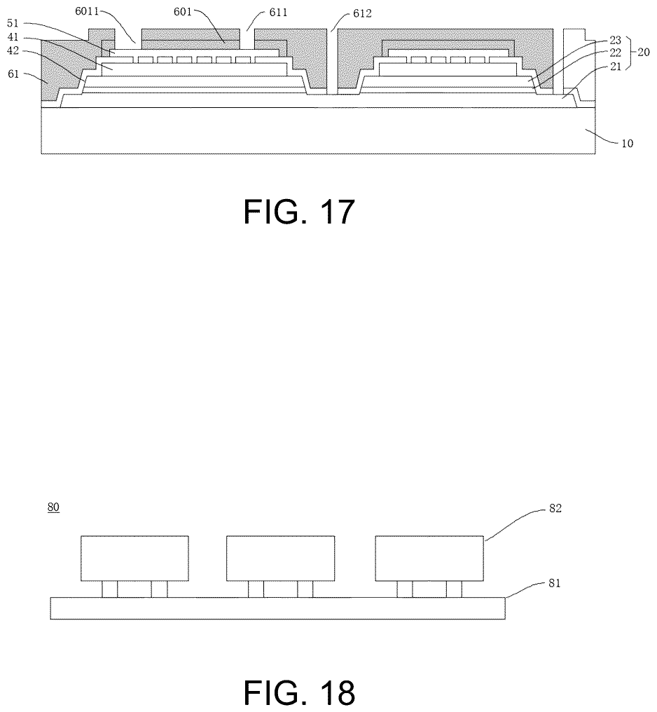

This embodiment provides yet another light-emitting diode, referring to FIG. 17, the same aspects as Embodiment One will not be described redundantly. The difference between this embodiment and Embodiment One is that in the light-emitting diode of this embodiment, the first insulation layer 61 includes an insulation barrier layer 601. The insulation barrier layer 601 covers the metal layer 51, and through holes 6011 are provided in the insulation barrier layer 601. The second electrode 32 is electrically connected to the metal layer 51 through the through holes 421 and the through holes 6011. Optionally, in a top view of the light-emitting diode, the through holes 421 and the through holes 6011 at least partially overlap each other, so that the second electrode 32 is electrically connected to the metal layer 51 through the through holes 421 and the through holes 6011.

In an optional embodiment, a material of the insulation barrier layer 601 includes insulation materials that may have a barrier effect on the metal layer 51. For example, the material of the insulation barrier layer 601 includes aluminum oxide, etc., the insulation barrier layer 601 may be formed by an atomic deposition process and other methods. The first insulation layer 61 further includes an insulation filling layer. The insulation filling layer is formed on the second insulation layer 42, and covers the insulation barrier layer 601. Optionally, the material of the insulation filling layer may be substantially the same as or may be different from the material of the insulation barrier layer 601. For example the material of the insulation filling layer includes silicon oxide. By designing the insulation barrier layer 601 to wrap the metal layer 51, the components of the metal layer 51 may be blocked from thermal diffusion or electrical diffusion, and oxidation of the surface of the metal layer 51 that causes the reflectivity of the metal layer 51 to decrease may be avoided. The through holes 6011 that partially overlap with the through holes 421 are formed in the insulation barrier layer 601, thus ensuring that the second electrode 32 is electrically connected to the metal layer 51.

### Embodiment Six

This embodiment provides a light-emitting device 80, referring to FIG. 18, the light-emitting device 80 includes a circuit substrate 82 and a plurality of light-emitting elements 82 connected to the circuit substrate 81. The light-emitting elements 82 include any one of the light-emitting diodes in the aforementioned embodiments and combinations thereof. The light-emitting device 80 may be an LED backlight device, an RGB display device or other light-emitting device 80. Since the light-emitting device 80 includes the light-emitting diodes in the aforementioned embodiments, the light-emitting device 80 also has the advantageous effects of the aforementioned embodiments.

The above embodiments only exemplify the principles and effects of the present disclosure, and are not used to limit the present disclosure. Any person familiar with this technology may modify, change or combine the above embodiments without violating the spirit and scope of the present disclosure. Therefore, all equivalent modifications or changes completed by those with ordinary knowledge in the technical field without departing from the spirit and technical concept disclosed in the present disclosure should still be covered by the claims of the present disclosure.

What is claimed is:

1. A light-emitting diode, comprising:
an epitaxial stack, comprising a first semiconductor layer, an active layer and a second semiconductor layer stacked in sequence, wherein the epitaxial stack has a trench, the trench penetrates the second semiconductor layer, the active layer and a portion of the first semiconductor layer to expose a partial surface of the first semiconductor layer;
an insulation layer, formed on the epitaxial stack, wherein the insulation layer is provided with a first through hole and a second through hole;
a connection electrode, formed on the insulation layer, and comprising a first electrode and a second electrode, wherein the first electrode is electrically connected to the first semiconductor layer through the second through hole, the second electrode is electrically connected to the second semiconductor layer through the first through hole, the first electrode comprises a first electrode layer formed on the insulation layer and a second electrode layer partially formed on the first electrode layer, a portion of the second electrode layer is in contact with the surface of the first semiconductor layer exposed by the trench through the second through hole, the first electrode layer comprises a first contact layer contacting the insulation layer, the second electrode layer comprises a second contact layer contacting the surface of the first semiconductor layer, wherein a thickness of the second contact layer is less than a thickness of the first contact layer.

2. The light-emitting diode according to claim 1, wherein the first contact layer is a metal chromium layer, a metal nickel layer or a metal titanium layer, and the thickness of the first contact layer is 10 Å˜100 Å;
the second contact layer is a metal chromium layer, a metal nickel layer or a metal titanium layer, and the thickness of the second contact layer is 3 Å˜25 Å.

3. The light-emitting diode according to claim 1, wherein the first electrode layer further comprises a first metal reflective layer formed on the first contact layer, the second electrode layer further comprises a second metal reflective layer formed on the second contact layer, and a thickness of the first metal reflective layer is equal to a thickness of the second metal reflective layer.

4. The light-emitting diode according to claim 1, wherein a reflectivity of the first electrode layer is less than a reflectivity of the second electrode layer.

5. The light-emitting diode according to claim 1, wherein the second electrode layer has a first portion in contact with the first electrode layer and a second portion in contact with the first semiconductor layer, in a top view of the light-emitting diode along a thickness direction of the epitaxial stack, an area of the first portion is larger than an area of the second portion.

6. The light-emitting diode according to claim 1, wherein a plurality of recess portions are further provided at an outer periphery of the epitaxial stack, the recess portions penetrate the second semiconductor layer, the active layer and a portion of the first semiconductor layer along a thickness direction of the epitaxial stack to expose the partial surface of the first semiconductor layer, and the second electrode layer contacts the partial surface of the first semiconductor layer exposed by the recess portions through the second through hole.

7. The light-emitting diode according to claim 6, further comprising a substrate, wherein the epitaxial stack is formed on the substrate;
in a top view of the light-emitting diode, a distance between the first electrode layer and an edge of the substrate is greater than a distance between the second electrode layer and the edge of the substrate, with a distance between an edge of the first electrode layer and an edge of the second electrode layer being an electrode layer edge spacing, a value of the electrode layer edge spacing in a region where the recess portions are located is greater than a value of the electrode layer edge spacing at other regions of the light-emitting diode.

8. The light-emitting diode according to claim 1, wherein the second electrode comprises a third electrode layer and a fourth electrode layer, the third electrode layer comprises a third contact layer formed on the insulation layer, the fourth electrode layer comprises a fourth contact layer formed on the third electrode layer, a thickness of the third contact layer is greater than a thickness of the fourth contact layer.

9. The light-emitting diode according to claim 8, wherein a first gap is provided between the first electrode layer and the third electrode layer, a second gap is provided between the second electrode layer and the fourth electrode layer, and a width of the first gap is less than a width of the second gap.

10. The light-emitting diode according to claim 8, wherein the third electrode layer further comprises a third metal reflective layer formed on the third contact layer, the fourth electrode layer further comprises a fourth metal reflective layer formed on the fourth contact layer, and a thickness of the third metal reflective layer is equal to a thickness of the fourth metal reflective layer.

11. The light-emitting diode according to claim 8, wherein the third contact layer is a metal chromium layer, a metal nickel layer or a metal titanium layer, and the thickness of the third contact layer is 10 Å˜100 Å;
the fourth contact layer is a metal chromium layer, a metal nickel layer or a metal titanium layer, and the thickness of the fourth contact layer is 3 Å˜25 Å.

12. A light-emitting diode, comprising:
an epitaxial stack, comprising a first semiconductor layer, an active layer and a second semiconductor layer sequentially stacked, wherein the epitaxial stack has a trench, the trench penetrates the second semiconductor layer, the active layer and a portion of the first semiconductor layer to expose a partial surface of the first semiconductor layer;
an insulation layer, formed on the epitaxial stack, wherein the insulation layer is provided a first through hole and a second through hole;
a connection electrode, formed on the insulation layer, and comprising a first electrode and a second electrode, wherein the first electrode is electrically connected to the first semiconductor layer through the second through hole, the second electrode is electrically connected to the second semiconductor layer through the first through hole, the first electrode comprises a contact layer, the contact layer comprises a first contact portion formed on the insulation layer and a second contact portion formed on the partial surface of the first semiconductor layer exposed by the trench, and a thickness of the second contact portion is less than a thickness of the first contact portion.

13. The light-emitting diode according to claim 12, wherein in a top view of the light-emitting diode, an area of the first contact portion is larger than an area of the second contact portion.

14. The light-emitting diode according to claim 12, wherein the light-emitting diode further comprises a transparent conductive layer and a metal layer, the insulation layer comprises a first insulation layer and a second insulation layer;
the transparent conductive layer is formed on the epitaxial stack;
the second insulation layer is formed on the epitaxial stack, covering the transparent conductive layer, wherein the second insulation layer has a third through hole and a fourth through hole, the third through hole exposes the transparent conductive layer, and the fourth through hole exposes the partial surface of the first semiconductor layer exposed by the trench;
the metal layer is formed on the second insulation layer, and in contact with the transparent conductive layer through the third through hole;
the first insulation layer is formed on the metal layer and covers the second insulation layer.

15. The light-emitting diode according to claim 14, wherein the transparent conductive layer is provided with a plurality of fifth through holes spaced apart from each other, the plurality of fifth through holes expose the second semiconductor layer and are arranged in a staggered manner with the third through hole.

16. The light-emitting diode according to claim 14, wherein the light-emitting diode further comprises a metal barrier layer, formed on the second insulation layer and covering the metal layer, the first through hole exposes the metal barrier layer, and the second electrode contacts the metal barrier layer through the first through hole.

17. The light-emitting diode according to claim 14, wherein the second insulation layer comprises an insulation barrier layer covering the metal layer, the insulation barrier layer is provided with a sixth through hole, and the second electrode contacts the metal layer through the first through hole and the sixth through hole.

18. The light-emitting diode according to claim 14, further comprising:
a third insulation layer, located on a side of the first insulation layer away from the second insulation layer, and covering the connection electrode, wherein the third insulation layer is provided with an opening exposing the connection electrode;
a pad electrode, located on a side of the connection electrode away from the first insulation layer, and electrically connected to the connection electrode through the opening.
